(19) United States
(12) Patent Application Publication
(10) Pub. No.: US 2016/0173229 A1
(43) Pub. Date: Jun. 16, 2016

(54) METHOD AND DEVICE FOR RECEIVING SIGNALS IN WIRELESS ACCESS SYSTEM

(71) Applicant: LG ELECTRONICS INC., Seoul (KR)

(72) Inventors: Kwangseok NOH, Seoul (KR); Jinmin KIM, Seoul (KR); Kukheon CHOI, Seoul (KR); Jaehoon CHUNG, Seoul (KR); Kitae KIM, Seoul (KR)

(73) Assignee: LG ELECTRONICS INC., Seoul (KR)

(21) Appl. No.: 14/902,771

(22) PCT Filed: Aug. 5, 2014
(86) PCT No.: PCT/KR2014/007216

§ 371 Date: Jan. 4, 2016

Related U.S. Application Data
(60) Provisional application No. 61/862,097, filed on Aug. 5, 2013.

(51) Int. Cl. H04L 1/00; H03M 13/11; H03M 13/29; H04W 72/08; H04L 5/00

(52) U.S. Cl. CPC H04L 1/0045; H04W 72/085; H04L 5/006; H03M 13/2909; H03M 13/1102; H04W 88/02

(57) ABSTRACT

The present invention relates to a method for receiving signals in a wireless communication system. A method by which a terminal receives signals in a wireless communication system, according to one embodiment of the present invention, can comprise the steps of: receiving N signals through N channels; and decoding the N signals by using a low density parity check (LDPC) sum-product channel decoder, wherein a first weight value is applied to a variable node of the LDPC sum-product channel decoder, a second weight value is applied to a reception signal node thereof, and the first weight value is less than 1 for channels of which a channel state has a reference value or less among the N channels.

### TECHNICAL FIELD

The present invention relates to a wireless communication system, and more particularly, to a method of receiving signals passing through a multi-channel environment via multiple paths efficiently and apparatus for supporting the same.

### BACKGROUND ART

Wireless communication systems have been widely used to provide various kinds of communication services such as voice or data services. Generally, a wireless communication system is a multiple access system that can communicate with multiple users by sharing available system resources (bandwidth, transmission (Tx) power, and the like). A variety of multiple access systems can be used. For example, a Code Division Multiple Access (CDMA) system, a Frequency Division Multiple Access (FDMA) system, a Time Division Multiple Access (TDMA) system, an Orthogonal Frequency Division Multiple Access (OFDMA) system, a Single Carrier Frequency-Division Multiple Access (SC-FDMA) system, a Multi-Carrier Frequency Division Multiple Access (MC-FDMA) system, and the like.

### DISCLOSURE OF THE INVENTION

### Technical Task

One technical task of the present invention is to provide a method of receiving signals passing through a multi-channel environment via multiple paths efficiently in a wireless access system.

Another technical task of the present invention is to provide an apparatus for supporting these methods.

Technical tasks obtainable from the present invention are non-limited by the above-mentioned technical task. And, other unmentioned technical tasks can be clearly understood from the following description by those having ordinary skill in the technical field to which the present invention pertains.

### Technical Solutions

To achieve these objects and other advantages and in accordance with the purpose of the invention, as embodied and broadly described herein, a method of receiving a signal, which is received by a user equipment in a wireless communication system, according to one embodiment of the present invention may include receiving N signals through N channels and decoding the N signals using an Low density parity check (LDPC) sum-product channel decoder, wherein a first weight factor is applied to a variable node of the LDPC sum-product channel decoder, wherein a second weight factor is applied to a received signal node, and wherein the first weight factor is smaller than 1 for a channel having a channel state equals to or smaller than a reference value among the N channels.

In another aspect of the present invention, as embodied and broadly described herein, a user equipment, which receives a signal in a wireless communication system, according to another embodiment of the present invention may include a radio frequency (RF) unit and a processor configured to receive N signals through N channels, the processor configured to decode the N signals using an Low density parity check (LDPC) sum-product channel decoder, wherein a first weight factor is applied to a variable node of the LDPC sum-product channel decoder, wherein a second weight factor is applied to a received signal node, and wherein the first weight factor is smaller than 1 for a channel having a channel state equals to or smaller than a reference value among the N channels.

The following matters may be applied in common to the above embodiments according to the present inventions.

The first weight factor may be separately set for each of the N channels.

The second weight factor may be set to 0 if the channel state is equals to or smaller than a minimum value.

The N signals may be separately transmitted on the N channels after being sequentially processed according to a single channel coding module, a modulation module and a resource mapping module.

Each of the first weight factor and the second weight factor may be determined in accordance with a strength of the signal.

The strength of the signal may be determined based on Reference signal received power (RSRP).

The strength of the signal may be determined based on Received signal strength indicator (RSSI).

The above general description and the following detailed description of the present invention are exemplary and provided to additionally describe the invention disclosed in the appended claims.

### Advantageous Effects

According to embodiments of the present invention, the following effect can be obtained.

First of all, signals passing through a multi-channel environment via multiple paths in a wireless access system can be efficiently received.

Effects obtainable from the present invention are non-limited by the above mentioned effect. And, other unmentioned effects can be clearly understood from the following description by those having ordinary skill in the technical field to which the present invention pertains.

### DESCRIPTION OF DRAWINGS

FIG. 1 illustrates a network structure of an E-UMTS as an exemplary wireless communication system.

FIG. 2 illustrates a control plane and a user plane of a radio interface protocol architecture between a UE and an E-UTRAN based on a 3GPP radio access network standard.

FIG. 3 illustrates physical channels used in a 3GPP system and a general signal transmission method using the same.

FIG. 4 illustrates the structure of a radio frame used in an LTE system.

FIG. 5 illustrates the structure of a downlink radio frame used in an LTE system.

FIG. 6 illustrates the structure of an uplink subframe used in an LTE system.

FIG. 7 illustrates the configuration of a general MIMO communication system.

FIGS. 8 and 9 illustrate periodic reporting of channel state information.

FIG. 10 is a block diagram for one example of a carrier aggregation system capable of both an intra band transmission and an inter band transmission.

FIG. 11 shows one example of a communication system having a received power imbalance of a received signal occur therein.

FIG. 12 represents carrier aggregation applied MAC-PHY interface. FIG. 12(b) is a block diagram having MAC-PHY interface different from the block diagram shown in FIG. 11.

FIG. 13 shows one example of a multi-antennal transmitting system using 2 transceiving antennas and 2 receiving antennas.

FIG. 14 shows a bipartite graph of LDPC coding.

FIG. 15 shows a bipartite graph of an LPDC decoder, to which a scaling factor is applied, in a system for N stream transmissions.

FIG. 16 shows one example of a base station and user equipment applicable to one embodiment of the present invention.

### BEST MODE FOR INVENTION

The following embodiments are proposed by combining constituent components and characteristics of the present invention according to a predetermined format. The individual constituent components or characteristics should be considered to be optional factors on the condition that there is no additional remark. If required, the individual constituent components or characteristics may not be combined with other components or characteristics. Also, some constituent components and/or characteristics may be combined to implement the embodiments of the present invention. The order of operations to be disclosed in the embodiments of the present invention may be changed to another. Some components or characteristics of any embodiment may also be included in other embodiments, or may be replaced with those of the other embodiments as necessary.

The embodiments of the present invention are disclosed on the basis of a data communication relationship between a Base Station (BS) and a terminal. In this case, the BS is used as a terminal node of a network via which the BS can directly communicate with the terminal. Specific operations to be conducted by the BS in the present invention may also be conducted by an upper node of the BS as necessary.

In other words, it will be obvious to those skilled in the art that various operations for enabling the BS to communicate with the terminal in a network composed of several network nodes including the BS will be conducted by the BS or other network nodes other than the BS. The term “BS” may be replaced with a fixed station, Node B, evolved Node B (eNB or eNode B), or an Access Point (AP) as necessary. The term “relay” may be replaced with a Relay Node (RN) or a Relay Station (RS). The term “terminal” may also be replaced with a User Equipment (UE), a Mobile Station (MS), a Mobile Subscriber Station (MSS) or a Subscriber Station (SS) as necessary.

It should be noted that specific terms disclosed in the present invention are proposed for the convenience of description and better understanding of the present invention, and the use of these specific terms may be changed to another format within the technical scope or spirit of the present invention.

In some instances, well-known structures and devices are omitted in order to avoid obscuring the concepts of the present invention and the important functions of the structures and devices are shown in block diagram form. The same reference numbers will be used throughout the drawings to refer to the same or like parts.

Embodiments of the present invention are supported by standard documents disclosed for at least one of wireless access systems including an Institute of Electrical and Electronics Engineers (IEEE) 802 system, a 3^{rd} Generation Project Partnership (3GPP) system, a 3GPP Long Term Evolution (LTE) system, and a 3GPP2 system. In particular, the steps or parts, which are not described to clearly reveal the technical idea of the present invention, in the embodiments of the present invention may be supported by the above documents. All terminology used herein may be supported by at least one of the above-mentioned documents.

The following embodiments of the present invention can be applied to a variety of wireless access technologies, for example, Code Division Multiple Access (CDMA), Frequency Division Multiple Access (FDMA), Time Division Multiple Access (TDMA), Orthogonal Frequency Division Multiple Access (OFDMA), Single Carrier Frequency Division Multiple Access (SC-FDMA), and the like. CDMA may be embodied with wireless (or radio) technology such as Universal Terrestrial Radio Access (UTRA) or CDMA2000. TDMA may be embodied with wireless (or radio) technology such as Global System for Mobile communications (GSM)/General Packet Radio Service (GPRS)/Enhanced Data Rates for GSM Evolution (EDGE). OFDMA may be embodied with wireless (or radio) technology such as Institute of Electrical and Electronics Engineers (IEEE) 802.11 (Wi-Fi), IEEE 802.16 (WiMAX), IEEE 802-20, and Evolved UTRA (E-UTRA). UTRA is a part of Universal Mobile Telecommunications System (UMTS). 3rd Generation Partnership Project Long Term Evolution (3GPP LTE) is a part of Evolved UMTS (E-UMTS), which uses E-UTRA. 3GPP LTE employs OFDMA in downlink and employs SC-FDMA in uplink. LTE-Advanced (LTE-A) is an evolution of 3GPP LTE. WiMAX can be explained by an IEEE 802.16e (WirelessMAN-OFDMA Reference System) and an advanced IEEE 802.16m (WirelessMAN-OFDMA Advanced System). For clarity, the following description focuses on the 3GPP LTE and LTE-A systems. However, the technical features of the present invention are not limited thereto.

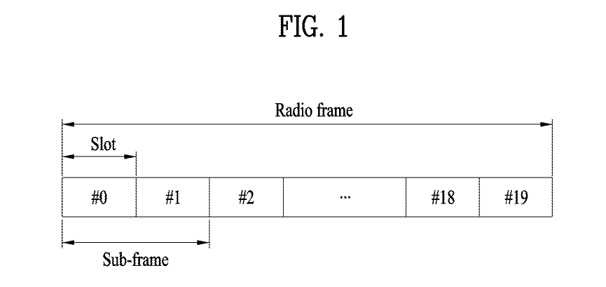

The structure of a downlink radio frame will be described with reference to FIG. 1.

In a cellular Orthogonal Frequency Division Multiplexing (OFDM) radio packet communication system, uplink/downlink data packets are transmitted in subframes. One subframe is defined as a predetermined time interval including a plurality of OFDM symbols. The 3GPP LTE standard supports a type 1 radio frame structure applicable to Frequency Division Duplex (FDD) and a type 2 radio frame structure applicable to Time Division Duplex (TDD).

FIG. 1 is a diagram illustrating the structure of the type 1 radio frame. A downlink radio frame includes 10 subframes, and one subframe includes two slots in the time domain. A time required for transmitting one subframe is defined as a Transmission Time Interval (TTI). For example, one subframe may have a length of 1 ms and one slot may have a length of 0.5 ms. One slot may include a plurality of OFDM symbols in the time domain and include a plurality of Resource Blocks (RBs) in the frequency domain. Since the 3GPP LTE system uses OFDMA in downlink, the OFDM symbol indicates one symbol duration. The OFDM symbol may be called an SC-FDMA symbol or symbol duration. An RB is a resource allocation unit including a plurality of contiguous subcarriers in one slot.

The number of OFDM symbols included in one slot may be changed according to the configuration of a Cyclic Prefix (CP). There are an extended CP and a normal CP. For example, the number of OFDM symbols included in one slot may be seven in case of a normal CP. In case of an extended CP, the length of one OFDM symbol is increased and thus the number of OFDM symbols included in one slot is less than that in case of a normal CP. In case of the extended CP, for example, the number of OFDM symbols included in one slot may be six. If a channel state is instable as is the case when a UE moves fast, the extended CP may be used in order to further reduce interference between symbols.

In case of a normal CP, since one slot includes seven OFDM symbols, one subframe includes 14 OFDM symbols. The first two or three OFDM symbols of each subframe may be allocated to a Physical Downlink Control Channel (PDCCH) and the remaining OFDM symbols may be allocated to a Physical Downlink Shared Channel (PDSCH).

The structure of the radio frame is only exemplary. Accordingly, the number of subframes included in a radio frame, the number of slots included in a subframe or the number of symbols included in a slot may be changed in various manners.

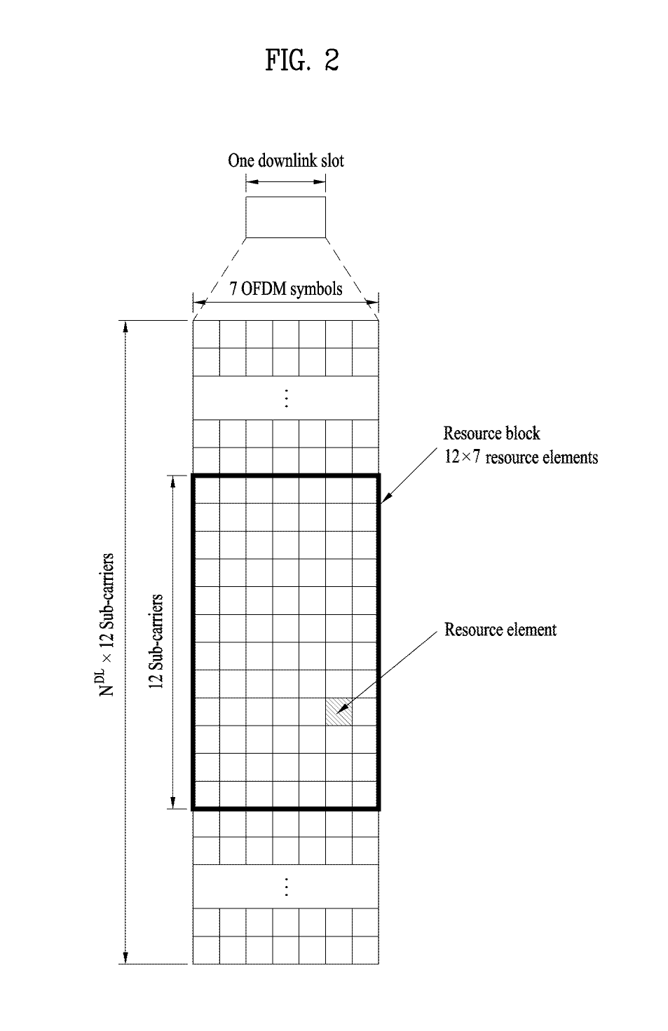

FIG. 2 is a diagram illustrating an example of a resource grid in one downlink slot. OFDM symbols are configured by the normal CP. Referring to FIG. 2, the downlink slot includes a plurality of OFDM symbols in the time domain and includes a plurality of RBs in the frequency domain. Although FIG. 2 exemplarily depicts that one downlink slot includes seven OFDM symbols and one RB includes 12 subcarriers, the present invention is not limited thereto. Each element of the resource grid is referred to as a Resource Element (RE). For example, an RE a(k,l) is located at a kth subcarrier and an lth OFDM symbol. In case of a normal CP, one RB includes 12□7 REs (in case of an extended CP, one RB includes 12□6 REs). Since the spacing between subcarriers is 15 kHz, one RB is about 180 kHz in the frequency domain. NDL denotes the number of RBs included in the downlink slot. NDL is determined based on a downlink transmission bandwidth set through Node B scheduling.

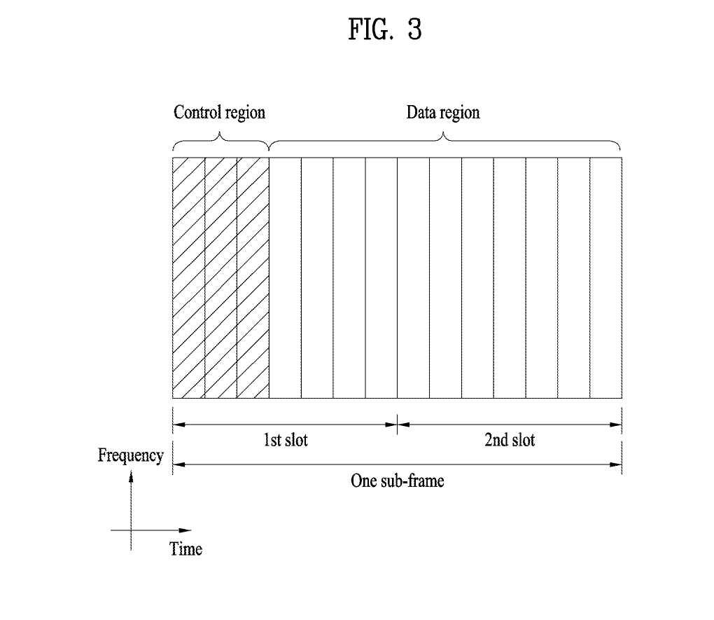

FIG. 3 is a diagram illustrating the structure of a downlink subframe. Up to three OFDM symbols at the start of a first slot of one subframe corresponds to a control region to which a control channel is allocated. The remaining OFDM symbols correspond to a data region to which a Physical Downlink Shared Channel (PDSCH) is allocated. A basic transmission unit is one subframe. That is, a PDCCH and a PDSCH are allocated across two slots. Examples of the downlink control channels used in the 3GPP LTE system include, for example, a Physical Control Format Indicator Channel (PCFICH), a Physical Downlink Control Channel (PDCCH), a Physical Hybrid automatic repeat request Indicator Channel (PHICH), etc. The PCFICH is located in the first OFDM symbol of a subframe, carrying information about the number of OFDM symbols used for control channels in the subframe. The PHICH includes a HARQ ACKnowledgment/Negative ACKnowledgment (ACK/NACK) signal as a response to an uplink transmission. The control information transmitted on the PDCCH is referred to as Downlink Control Information (DCI). The DCI includes uplink or downlink scheduling information or an uplink transmit power control command for a certain UE group. The PDCCH may include information about resource allocation and transmission format of a Downlink Shared Channel (DL-SCH), resource allocation information of an Uplink Shared Channel (UL-SCH), paging information of a Paging Channel (PCH), system information on the DL-SCH, information about resource allocation of an higher layer control message such as a Random Access Response (RAR) transmitted on the PDSCH, a set of transmit power control commands for individual UEs in a certain UE group, transmit power control information, information about activation of Voice over IP (VoIP), etc. A plurality of PDCCHs may be transmitted in the control region. A UE may monitor the plurality of PDCCHs. The PDCCHs are transmitted on an aggregation of one or several contiguous Control Channel Elements (CCEs). A CCE is a logical allocation unit used to provide the PDCCHs at a coding rate based on the state of a radio channel. The CCE includes a set of REs. A format and the number of available bits for the PDCCH are determined based on the correlation between the number of CCEs and the coding rate provided by the CCEs. The BS determines a PDCCH format according to DCI to be transmitted to the UE, and attaches a Cyclic Redundancy Check (CRC) to control information. The CRC is masked by a Radio Network Temporary Identifier (RNTI) according to the owner or usage of the PDCCH. If the PDCCH is for a specific UE, the CRC may be masked by a cell-RNTI (C-RNTI) of the UE. If the PDCCH is for a paging message, the CRC may be masked by a paging indicator identifier (P-RNTI). If the PDCCH is for system information (more specifically, a System Information Block (SIB)), the CRC may be masked by a system information identifier and a System Information RNTI (SI-RNTI). To indicate a random access response to a random access preamble received from the UE, the CRC may be masked by a random access-RNTI (RA-RNTI).

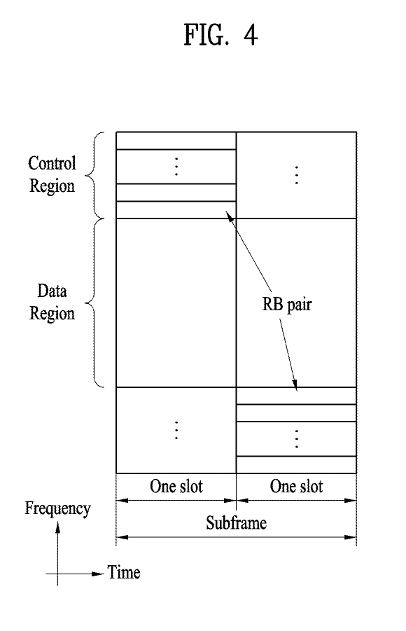

FIG. 4 is a diagram illustrating the structure of an uplink subframe. The uplink subframe may be divided into a control region and a data region in the frequency domain. A Physical Uplink Control Channel (PUCCH) including uplink control information is allocated to the control region. A Physical uplink Shared Channel (PUSCH) including user data is allocated to the data region. In order to maintain single carrier property, one UE does not simultaneously transmit the PUCCH and the PUSCH. A PUCCH for one UE is allocated to an RB pair in a subframe. The RBs of the RB pair occupy different subcarriers in two slots. Thus, the RB pair allocated to the PUCCH is “frequency-hopped” over a slot boundary.

Modeling of Multiple Input Multiple Output (MIMO) System

The MIMO system increases data transmission/reception efficiency using a plurality of Tx antennas and a plurality of Rx antennas. MIMO is an application of putting data segments received from a plurality of antennas into a whole message, without depending on a single antenna path to receive the whole message.

MIMO schemes are classified into spatial diversity and spatial multiplexing. Spatial diversity increases transmission reliability or a cell radius using diversity gain and thus is suitable for data transmission for a fast moving UE. In spatial multiplexing, multiple Tx antennas simultaneously transmit different data and thus high-speed data can be transmitted without increasing a system bandwidth.

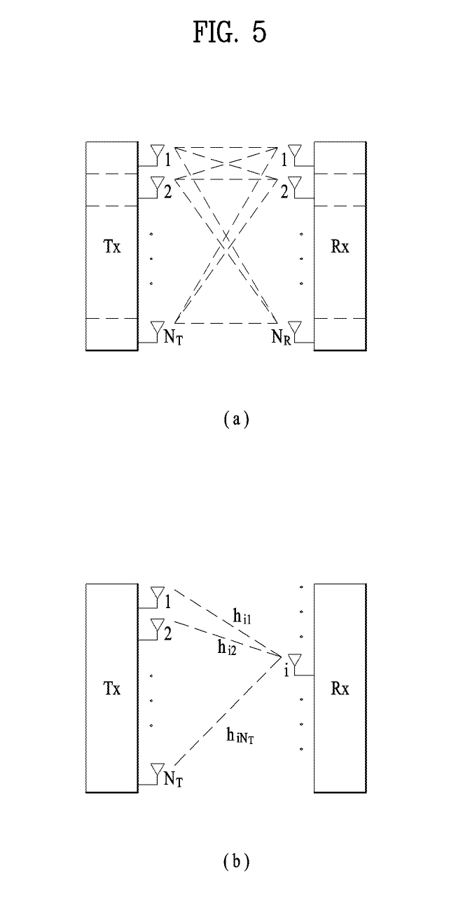

FIG. 5 illustrates the configuration of a wireless communication system supporting multiple antennas. Referring to FIG. 5(a), when the number of Transmission (Tx) antennas and the number of Reception (Rx) antennas are increased to NT and NR, respectively at both a transmitter and a receiver, a theoretical channel transmission capacity increases in proportion to the number of antennas, compared to use of a plurality of antennas at only one of the transmitter and the receiver. Therefore, transmission rate and frequency efficiency are remarkably increased. Along with the increase of channel transmission capacity, the transmission rate may be increased in theory to the product of a maximum transmission rate Ro that may be achieved in case of a single antenna and a rate increase rate Ri.

Rᵢ=min(Nₜ,N_{R}) [Equation 1]

For instance, a MIMO communication system with four Tx antennas and four Rx antennas may achieve a four-fold increase in transmission rate theoretically, relative to a single-antenna wireless communication system. Since the theoretical capacity increase of the MIMO wireless communication system was proved in the mid 1990's, many techniques have been actively studied to increase data rate in real implementation. Some of the techniques have already been reflected in various wireless communication standards including standards for 3G mobile communications, future-generation Wireless Local Area Network (WLAN), etc.

Concerning the research trend of MIMO up to now, active studies are underway in many respects of MIMO, inclusive of studies of information theory related to calculation of multi-antenna communication capacity in diverse channel environments and multiple access environments, studies of measuring MIMO radio channels and MIMO modeling, studies of time-space signal processing techniques to increase transmission reliability and transmission rate, etc.

Communication in a MIMO system with NT Tx antennas and NR Rx antennas will be described in detail through mathematical modeling.

Regarding a transmission signal, up to NT pieces of information can be transmitted through the NT Tx antennas, as expressed as the following vector.

s=└s₁,s₂, . . . ,s_{N}_{_{T}}┘^{T} [Equation2]

A different transmission power may be applied to each piece of transmission information, s₁, s₂, . . . , s _{N}_{_{T}}. Let the transmit power levels of the transmission information be denoted by p₁, p₂, . . . p_{N}_{_{T}}, respectively. Then the transmission power-controlled transmission information vector may be given as

ŝ=[ŝ₁, ŝ₂, . . . , ŝ_{N}_{_{T}}]^{T}=[P₁s₁, P₂s₂, . . . , P_{N}_{_{T}}s_{N}_{_{T}}]^{T} [Equation 3]

The transmission power-controlled transmission information vector ŝ may be expressed as follows, using a diagonal matrix P of transmission power.

$$\hat{s} = [ \begin{matrix}{P}_{1} & & & 0 \\ & {P}_{2} & & \\ & & ⋱ & \\ 0 & & & {P}_{{N}_{T}}\end{matrix} ] [ \begin{matrix}{s}_{1} \\ {s}_{2} \\ ⋮ \\ {s}_{{N}_{T}}\end{matrix} ] = Ps \qquad [ Equation 4 ]$$

N_{T} transmission signals x₁, x₂, . . . , x_{N}_{_{T}} may be generated by multiplying the transmission power-controlled information vector ŝ by a weight matrix W. The weight matrix W functions to appropriately distribute the transmission information to the Tx antennas according to transmission channel states, etc. These N_{T} transmission signals x₁, x₂, . . . , x_{N}_{_{T}} are represented as a vector x, which may be determined as

$$x = [ \begin{matrix}{x}_{1} \\ {x}_{2} \\ ⋮ \\ {x}_{i} \\ ⋮ \\ {x}_{{N}_{T}}\end{matrix} ] [ \begin{matrix}{w}_{11} & {w}_{12} & … & {w}_{1 {N}_{T}} \\ {w}_{21} & {w}_{22} & … & {w}_{2 {N}_{T}} \\ ⋮ & & ⋱ & \\ {w}_{i 1} & {w}_{i 2} & … & {w}_{{iN}_{T}} \\ ⋮ & & ⋱ & \\ {w}_{{N}_{T} 1} & {w}_{{N}_{T} 2} & … & {w}_{{N}_{T} {N}_{T}}\end{matrix} ] [ \begin{matrix}{\hat{s}}_{1} \\ {\hat{s}}_{2} \\ ⋮ \\ {\hat{s}}_{j} \\ ⋮ \\ {\hat{s}}_{{N}_{T}}\end{matrix} ] = W \hat{s} = WPs \qquad [ Equation 5 ]$$

Here, Wᵢⱼ denotes a weight between a jth piece of information and an ith Tx antenna and W is a precoding matrix.

The transmitted signal x may be differently processed using according to two schemes (for example, spatial diversity and spatial multiplexing). In spatial multiplexing, different signals are multiplexed and transmitted to a receiver such that elements of information vector(s) have different values. In spatial diversity, the same signal is repeatedly transmitted through a plurality of channel paths such that elements of information vector(s) have the same value. Spatial multiplexing and spatial diversity may be used in combination. For example, the same signal may be transmitted through three Tx antennas in spatial diversity, while the remaining signals may be transmitted to the receiver in spatial multiplexing.

Given NR Rx antennas, signals received at the Rx antennas, y₁, y₂, . . . y_{N}_{_{R}} may be represented as the following vector.

y=[y₁, y₂, . . . , y_{N}_{_{R}}]^{T} [Equation 6]

When channels are modeled in the MIMO wireless communication system, they may be distinguished according to the indexes of Tx and Rx antennas. A channel between a jth Tx antenna and an ith Rx antenna is denoted by hij. Notably, the index of an Rx antenna precedes the index of a Tx antenna in hij.

FIG. 5(b) illustrates channels from NT Tx antennas to an ith Rx antenna. The channels may be collectively represented as a vector or a matrix. Referring to FIG. 5(b), the channels from the NT Tx antennas to the ith Rx antenna may be expressed as

hᵢ^{T}=[yᵢ₁, yᵢ₂, . . . , h_{iN}_{_{T}}] [Equation 7]

Hence, all channels from the N_{T} Tx antennas to the N_{R} Rx antennas may be expressed as the following matrix.

$$H = [ \begin{matrix}{h}_{1}^{T} \\ {h}_{2}^{T} \\ ⋮ \\ {h}_{i}^{T} \\ ⋮ \\ {h}_{{N}_{R}}^{T}\end{matrix} ] [ \begin{matrix}{h}_{11} & {h}_{12} & … & {h}_{1 {N}_{T}} \\ {h}_{21} & {h}_{22} & … & {h}_{2 {N}_{T}} \\ ⋮ & & ⋱ & \\ {h}_{i 1} & {h}_{i 2} & … & {h}_{{iN}_{T}} \\ ⋮ & & ⋱ & \\ {h}_{{N}_{R} 1} & {h}_{{N}_{R} 2} & … & {h}_{{N}_{R} {N}_{T}}\end{matrix} ] \qquad [ Equation 8 ]$$

Actual channels experience the above channel matrix H and then are added with Additive White Gaussian Noise (AWGN). The AWGN added to the NR Rx antennas is given as the following vector.

n=[n₁, n₂, . . . , n_{N}_{_{R}}]^{T} [Equation 9]

From the above mathematical modeling, the received signal vector is given as

$$y = [ \begin{matrix}{y}_{1} \\ {y}_{2} \\ ⋮ \\ {y}_{i} \\ ⋮ \\ {y}_{{N}_{R}}\end{matrix} ] [ \begin{matrix}{h}_{11} & {h}_{12} & … & {h}_{1 {N}_{T}} \\ {h}_{21} & {h}_{22} & … & {h}_{2 {N}_{T}} \\ ⋮ & & ⋱ & \\ {h}_{i 1} & {h}_{i 2} & … & {h}_{{iN}_{T}} \\ ⋮ & & ⋱ & \\ {h}_{{N}_{R} 1} & {h}_{{N}_{R} 2} & … & {h}_{{N}_{R} {N}_{T}}\end{matrix} ] [ \begin{matrix}{x}_{1} \\ {x}_{2} \\ ⋮ \\ {x}_{j} \\ ⋮ \\ {x}_{{N}_{T}}\end{matrix} ] + [ \begin{matrix}{n}_{1} \\ {n}_{2} \\ ⋮ \\ {n}_{i} \\ ⋮ \\ {n}_{{N}_{R}}\end{matrix} ] = Hx + n \qquad [ Equation 10 ]$$

The numbers of rows and columns in the channel matrix H representing channel states are determined according to the numbers of Rx and Tx antennas. Specifically, the number of rows in the channel matrix H is equal to the number of Rx antennas, NR and the number of columns in the channel matrix H is equal to the number of Tx antennas, NT. Hence, the channel matrix H is of size NR×NT.

The rank of a matrix is defined as the smaller between the number of independent rows and the number of independent columns in the matrix. Accordingly, the rank of the matrix is not larger than the number of rows or columns of the matrix. The rank of the channel matrix H, rank(H) satisfies the following constraint.

rank(H)≦min(N_{T}, N_{R}) [Equation 11]

In MIMO transmission, the term “rank” denotes the number of paths for independently transmitting signals, and the term “number of layers” denotes the number of signal streams transmitted through respective paths. In general, since a transmitter transmits as many layers as the number of ranks used for signal transmission, the rank has the same meaning as the number of layers unless otherwise noted.

Reference Signals (RSs)

In a wireless communication system, a packet is transmitted on a radio channel. In view of the nature of the radio channel, the packet may be distorted during the transmission. To receive the signal successfully, a receiver should compensate for the distortion of the received signal using channel information. Generally, to enable the receiver to acquire the channel information, a transmitter transmits a signal known to both the transmitter and the receiver and the receiver acquires knowledge of channel information based on the distortion of the signal received on the radio channel. This signal is called a pilot signal or an RS.

In case of data transmission and reception through multiple antennas, knowledge of channel states between Tx antennas and Rx antennas is required for successful signal reception. Accordingly, an RS should exist for each Tx antenna.

In a mobile communication system, RSs are largely categorized into two types according to the purposes that they serve, RSs used for acquisition of channel information and RSs used for data demodulation. The former-type RSs should be transmitted in a wideband to enable UEs to acquire downlink channel information. Even UEs that do not receive downlink data in a specific subframe should be able to receive such RSs and measure them. When an eNB transmits downlink data, it transmits the latter-type RSs in resources allocated to the downlink data. A UE can perform channel estimation by receiving the RSs and thus demodulate data based on the channel estimation. These RSs should be transmitted in a data transmission region.

In the legacy 3GPP LTE system (e.g. one conforming to 3GPP LTE Release-8), two types of downlink RSs are defined for unicast service, Common RS (CRS) and Dedicated RS (DRS). CRS is used for CSI acquisition and measurement, for example, for handover. The CRS is also called a cell-specific RS. DRS is used for data demodulation, called a UE-specific RS. The legacy 3GPP LTE system uses the DRS only for data demodulation and the CRS for the two purposes of channel information acquisition and data demodulation.

CRSs, which are cell-specific, are transmitted across a wideband in every subframe. According to the number of Tx antennas at an eNB, the eNB may transmit CRSs for up to four antenna ports. For instance, an eNB with two Tx antennas transmits CRSs for antenna port 0 and antenna port 1. If the eNB has four Tx antennas, it transmits CRSs for respective four Tx antenna ports, antenna port 0 to antenna port 3.

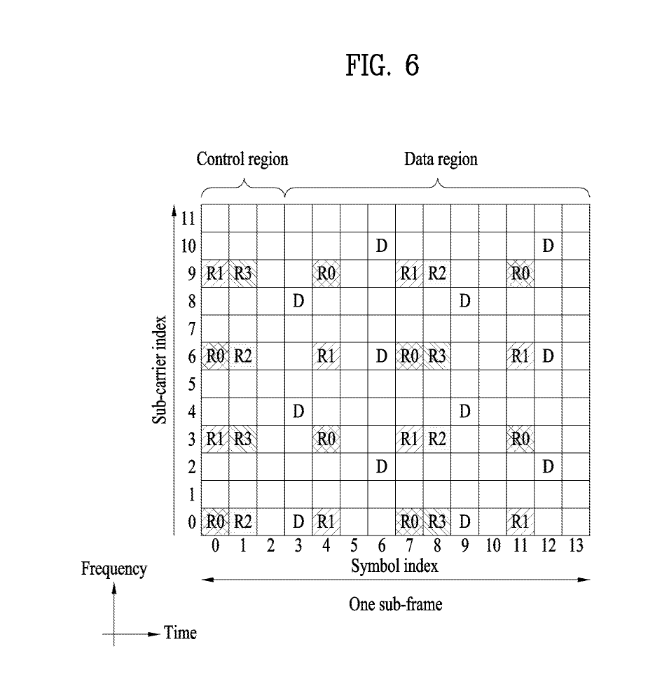

FIG. 6 illustrates a CRS and DRS pattern for an RB (including 14 OFDM symbols in time by 12 subcarriers in frequency in case of a normal CP) in a system where an eNB has four Tx antennas. In FIG. 6, REs labeled with ‘R0’, ‘R1’, ‘R2’ and ‘R3’ represent the positions of CRSs for antenna port 0 to antenna port 4, respectively. REs labeled with ‘D’ represent the positions of DRSs defined in the LTE system.

The LTE-A system, an evolution of the LTE system, can support up to eight Tx antennas. Therefore, it should also support RSs for up to eight Tx antennas, Because downlink RSs are defined only for up to four Tx antennas in the LTE system, RSs should be additionally defined for five to eight Tx antenna ports, when an eNB has five to eight downlink Tx antennas in the LTE-A system. Both RSs for channel measurement and RSs for data demodulation should be considered for up to eight Tx antenna ports.

One of significant considerations for design of the LTE-A system is backward compatibility. Backward compatibility is a feature that guarantees a legacy LTE terminal to operate normally even in the LTE-A system. If RSs for up to eight Tx antenna ports are added to a time-frequency area in which CRSs defined by the LTE standard are transmitted across a total frequency band in every subframe, RS overhead becomes huge. Therefore, new RSs should be designed for up to eight antenna ports in such a manner that RS overhead is reduced.

Largely, new two types of RSs are introduced to the LTE-A system. One type is CSI-RS serving the purpose of channel measurement for selection of a transmission rank, a Modulation and Coding Scheme (MCS), a Precoding Matrix Index (PMI), etc. The other type is Demodulation RS (DM RS) for demodulation of data transmitted through up to eight Tx antennas.

Compared to the CRS used for both purposes of measurement such as channel measurement and measurement for handover and data demodulation in the legacy LTE system, the CSI-RS is designed mainly for channel estimation, although it may also be used for measurement for handover. Since CSI-RSs are transmitted only for the purpose of acquisition of channel information, they may not be transmitted in every subframe, unlike CRSs in the legacy LTE system. Accordingly, CSI-RSs may be configured so as to be transmitted intermittently (e.g. periodically) along the time axis, for reduction of CSI-RS overhead.

When data is transmitted in a downlink subframe, DM RSs are also transmitted dedicatedly to a UE for which the data transmission is scheduled. Thus, DM RSs dedicated to a particular UE may be designed such that they are transmitted only in a resource area scheduled for the particular UE, that is, only in a time-frequency area carrying data for the particular UE.

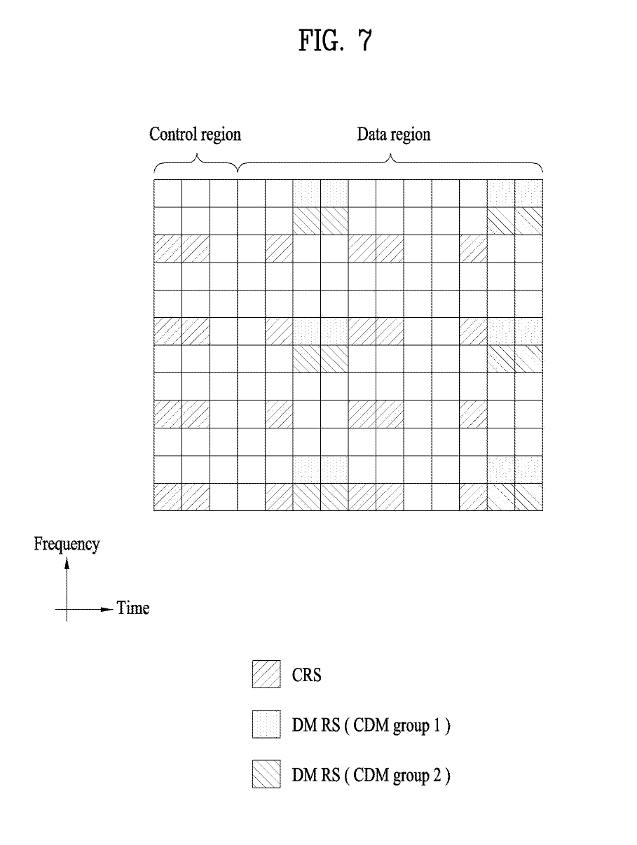

FIG. 7 illustrates an exemplary DM RS pattern defined for the LTE-A system. In FIG. 7, the positions of REs carrying DM RSs in an RB carrying downlink data (an RB having 14 OFDM symbols in time by 12 subcarriers in frequency in case of a normal CP) are marked. DM RSs may be transmitted for additionally defined four antenna ports, antenna port 7 to antenna port 10 in the LTE-A system. DM RSs for different antenna ports may be identified by their different frequency resources (subcarriers) and/or different time resources (OFDM symbols). This means that the DM RSs may be multiplezed in Frequency Division Multiplexing (FDM) and/or Time Division Multiplexing (TDM). If DM RSs for different antenna ports are positioned in the same time-frequency resources, they may be identified by their different orthogonal codes. That is, these DM RSs may be multiplexed in Code Division Multiplexing (CDM). In the illustrated case of FIG. 7, DM RSs for antenna port 7 and antenna port 8 may be located on REs of DM RS CDM group 1 through multiplexing based on orthogonal codes. Similarly, DM RSs for antenna port 9 and antenna port 10 may be located on REs of DM RS CDM group 2 through multiplexing based on orthogonal codes.

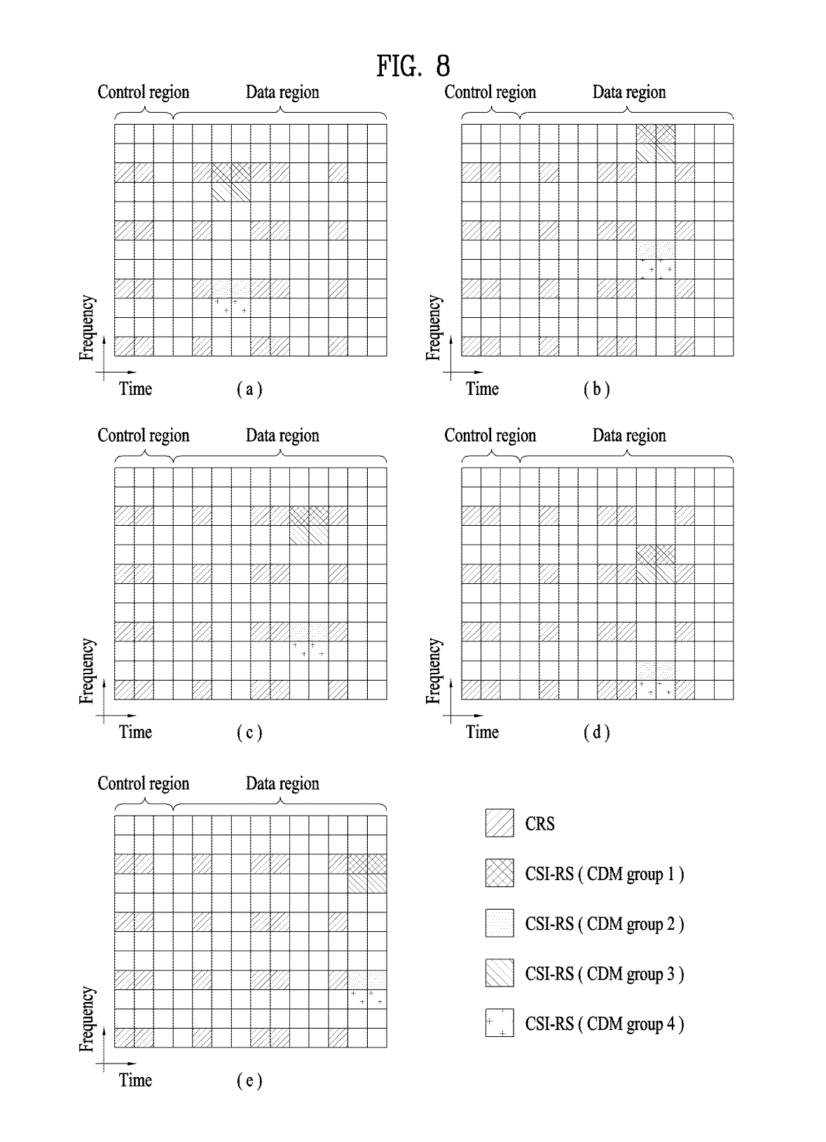

FIG. 8 illustrates exemplary CSI-RS patterns defined for the LTE-A system. In FIG. 8, the positions of REs carrying CSI-RSs in an RB carrying downlink data (an RB having 14 OFDM symbols in time by 12 subcarriers in frequency in case of a normal CP) are marked. One of the CSI-RS patterns illustrated in FIGS. 8(a) to 8(e) is available for any downlink subframe. CSI-RSs may be transmitted for eight antenna ports supported by the LTE-A system, antenna port 15 to antenna port 22. CSI-RSs for different antenna ports may be identified by their different frequency resources (subcarriers) and/or different time resources (OFDM symbols). This means that the CSI-RSs may be multiplexed in FDM and/or TDM. CSI-RSs positioned in the same time-frequency resources for different antenna ports may be identified by their different orthogonal codes. That is, these DM RSs may be multiplexed in CDM. In the illustrated case of FIG. 8(a), CSI-RSs for antenna port 15 and antenna port 16 may be located on REs of CSI-RS CDM group 1 through multiplexing based on orthogonal codes. CSI-RSs for antenna port 17 and antenna port 18 may be located on REs of CSI-RS CDM group 2 through multiplexing based on orthogonal codes. CSI-RSs for antenna port 19 and antenna port 20 may be located on REs of CSI-RS CDM group 3 through multiplexing based on orthogonal codes. CSI-RSs for antenna port 21 and antenna port 22 may be located on REs of CSI-RS CDM group 4 through multiplexing based on orthogonal codes. The same principle described with reference to FIG. 8(a) is applicable to the CSI-RS patterns illustrated in FIGS. 8(b) to 8(e).

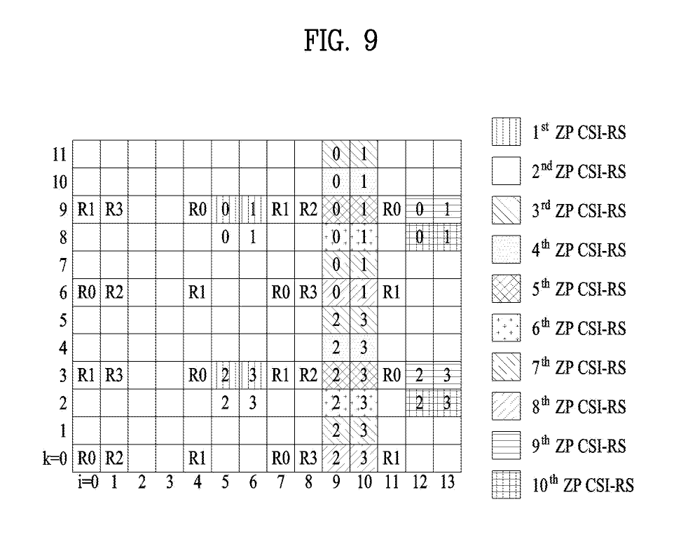

FIG. 9 is a diagram illustrating an exemplary Zero-Power (ZP) CSI-RS pattern defined in an LTE-A system. A ZP CSI-RS is largely used for two purposes. First, the ZP CSI-RS is used to improve CSI-RS performance. That is, one network may mute a CSI-RS RE of another network in order to improve CSI-RS measurement performance of the other network and inform a UE thereof of the muted RE by setting the muted RE to a ZP CSI-RS so that the UE may correctly perform rate matching. Second, the ZP CSI-RS is used for interference measurement for CoMP CQI calculation. That is, some networks may mute a ZP CRS-RS RE and a UE may calculate a CoMP CQI by measuring interference from the ZP CSI-RS.

The RS patterns of FIGS. 6 to 9 are purely exemplary and an RS pattern applied to various embodiments of the present invention is not limited to such specific RS patterns. In other words, even when an RS pattern different from the RS patterns of FIGS. 6 to 9 is defined and used, various embodiments of the present invention may be identically applied.

Carrier Aggregation & Received Power Imbalance

In LTE-Advanced (LTE-A), Carrier Aggregation (CA) used for a communication with a user equipment by combining a plurality of carriers is applicable. In doing so, when Carrier Aggregation (CA) is used, since different frequencies are used, it brings an effect of experiencing multiple paths. In particular, each path does not lie in the same environment due to frequency characteristics and path differences between transmitting/receiving antennas but has an independent channel environment.

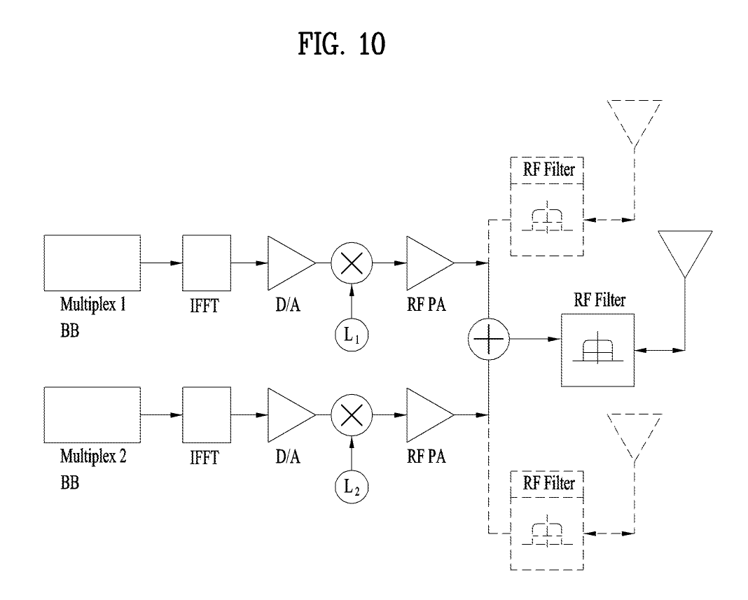

FIG. 10 shows one example of a block diagram capable of both an intra band transmission and an inter band transmission among block diagrams of a system using CA.

In FIG. 10, in case of performing carrier aggregation on an intra band, a single antenna is used. In case of performing carrier aggregation on an inter band, a dual antenna is used. Although a single antenna is used, since frequencies L1 and L2 of two carriers are different from each other, a receiving stage uses a band-pass filter, thereby being able to handle a corresponding band independently. In particular, owing to the different frequencies L1 and L2, one independent channel environment is provided per frequency as if using a dual antenna.

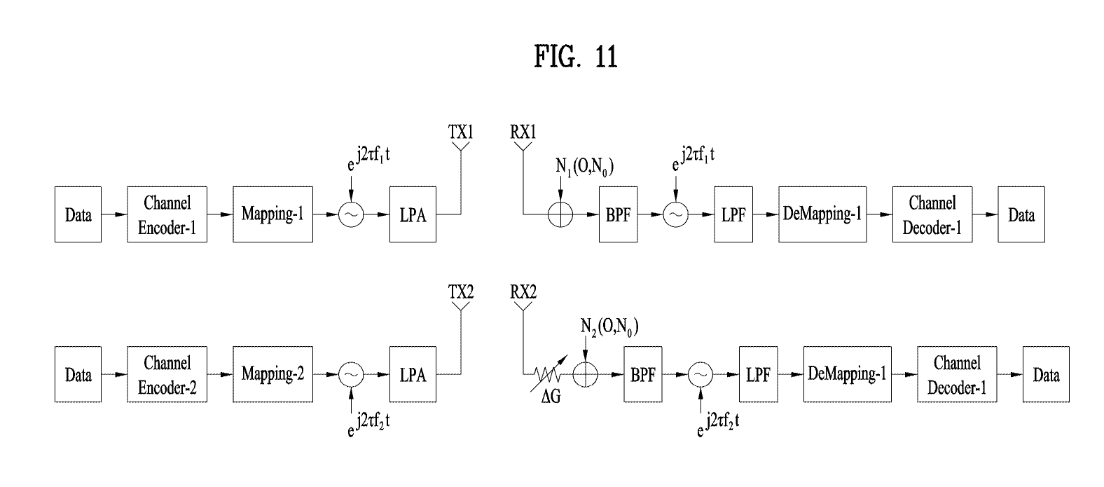

FIG. 11 shows one example of a communication system having a received power imbalance of a received signal occur therein. In case of LTE, a received signal power can be obtained from RSRP and RSSI. In case of RSRP, a measurement is possible in every subframe 1 ms. Meanwhile, as mentioned in the foregoing description, since a single antenna system has two channel environments according to a frequency, the received power imbalance is generated.

In a receiving stage shown in FIG. 11, an upper block and a lower block independently operate according to frequencies, respectively and channel environments of the upper block and the lower block are not equal to each other completely, the received power imbalance occurs. FIG. 11 shows a case that a received signal of the lower block is relatively weaker than that of the upper block and a corresponding difference can be denoted by AG.

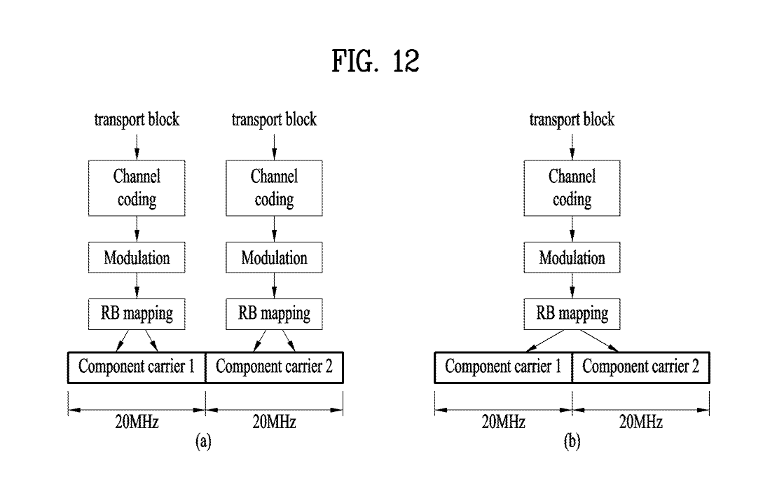

FIG. 12(a) represents FIG. 11 as carrier aggregation applied MAC-PHY interface. FIG. 12(b) is a block diagram having MAC-PHY interface different from, the block diagram shown in FIG. 11.

FIG. 12(a) shows a configuration applied to the current LTE standard. FIG. 12(b) shows a configuration that can be considered for a new system in the future despite being unable to support backward-capability considered by the current LTE standard. Since a link is independently configured per carrier, if a channel environment of a lower block is not good, there is no method for using an environment of an upper block. On the other hand, FIG. 12(b) is advantageous in that data can be restored using both of the channel environments of the upper and lower blocks through channel coding.

When the received power imbalance occurs, the object of the present invention is to increase error performance by applying a weight factor to a decoder of channel coding (channel decoder) used for a physical layer on the basis of a received signal power.

MIMO and Received Power Imbalance

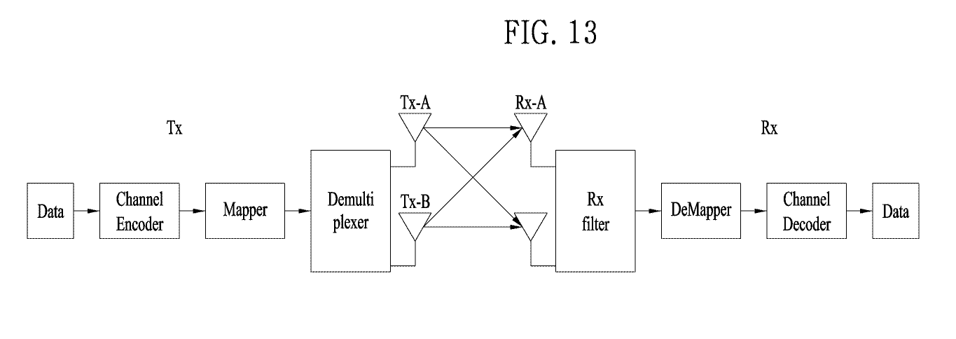

As another example of a scheme having multiple paths, there is MIMO (multiple input multiple output) multi-antenna (multiple antenna) system described with reference to FIG. 7. In order to use a diversity scheme for increasing transmission capacity or decreasing transmission error probability, multiple antennas are available for a transmitting/receiving stage. FIG. 13 shows one example of a multi-antennal transmitting system using 2 transceiving antennas and 2 receiving antennas.

The multiple-antenna system is the scheme of diversifying transmission paths for enhancing throughput or bit error rate through precoding appropriate for the diversified transmission paths. For instance, the transmitting/receiving stage may use at least two antennas each.

The receiving stage combines signals transmitted through various paths. An antenna Rx-A shown in FIG. 13 receives a signal transmitted from an antenna Tx-A and a signal transmitted from an antenna Tx-B through different paths (channels), respectively. In doing so, each of the paths does not lie in the same environment due to a distance between antennas and the like but has an independent channel environment.

According to one method for increasing error performance in a multi-antenna system, the same information is transmitted from each of the antenna Tx-A and the antenna Tx-B and the receiving stage then collects the transmitted informations. For instance, MRC (maximum ratio combining) method is available.

On the other hand, in order to increase a throughput, informations are transmitted to the antenna Tx-A and the antenna Tx-B through precoding of two streams and the receiving stage then uses the respectively received informations. Ongoing efforts are made to research and develop transmission schemes in a transmitting stage in consideration of passing through multiple channels. The primary object of these transmission schemes is to bring an effect of passing through an averaged channel environment to prevent transmission efficiency from decreasing due to experiencing a poor channel.

In this case, since channel environments for all paths are not perfectly same, the received power imbalance for each stream occurs in each receiving stage. In case of LTE, it is able to obtain the received power from RSTP, RSSI or a receiving filter (Rx filter). In general, if a channel environment becomes different from that of a previous timing, appropriate modulation and channel coding levels are determined again through feedback information. Yet, if a channel environment changes rapidly due to NLoS (Non-Line of Sight) or the like in a communication system using high frequency, it is unable to use a feedback based scheme.

The object of the present invention is to raise error performance in a manner as follows. First of all, if the received power imbalance occurs, a weight factor is applied to a channel decoder used in a physical layer based on a received power of a stream irrespective of a presence or non-presence of MIMO scheme use.

Error Performance Enhancing Method According to Present Invention

In case that the received power imbalance for a stream having passed through a multi-channel environment such as CA, multiple antennas and the like mentioned in the foregoing description occurs in a receiving stage, the object of the present invention is to enhance the error performance degraded due to the imbalance.

The object of an error performance enhancing method according to the present invention is to raise total error performance by applying a scaling factor to the Low density parity check (LDPC) channel decoder shown in FIG. 12(b).

LDPC sum-product decoding algorithm intended to be used by the present invention is a decoding scheme frequently used by a system that uses LDPC coding and has the best performance among LDPC decoding algorithms. In the other hand, a min-sum algorithm has decoding performance poorer than that of the sum-product algorithm but has a very small quantity of decoding operation. The min-sum algorithm frequently uses a weight factor called a scaling factor. In particular, a value of soft information used by a decoder can be changed in accordance with a scaling factor. And, the scaling factor is determined on the basis of simulation performance.

According to the present invention, in order to change a soft information value in the sum-product algorithm, it is able to use a weight factor determined on the basis of a received power (i.e., a received signal power).

The features of the present invention are applicable to a general multi-antenna transmission capable of performing multi-antenna transmission. For clarity of the following description, 2×2 multi-antenna is taken as one example. The 2×2 multi-antenna is able to transmit maximum 2 streams. The number of the streams increases in proportion to the increasing number of the transmitting/receiving antennas.

In a multi-antenna system, a receiving stage can identify each stream and is able to calculate a signal power of a corresponding stream from a receiving filter. Moreover, if the 2×2 multi-antenna uses two frequencies, it can be represented as CA having 2 multi-paths in FIG. 12(b). The present invention may be applicable to a case that the number of transmitting/receiving antennas is increased in such a system as multiple antennas or CA. In such a system, those skilled in the art, to which the present invention pertains, can identify streams.

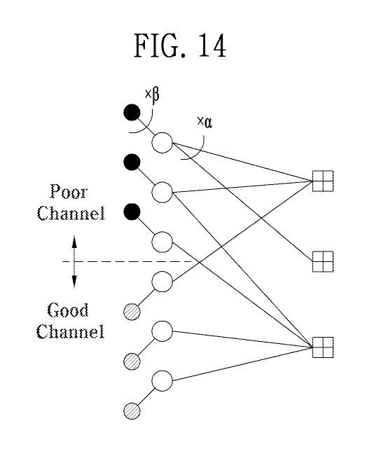

FIG. 14 shows a bipartite graph of LDPC coding.

For clarity of the description with reference to FIG. 14, a signal having passed through a relatively poor channel and a signal having passed through a good channel are distinguished from each other in a manner of being disposed on an upper part and a lower part of the drawing. It is apparent to those skilled in the art, to which the present invention pertains, that the sequence of the variable nodes shown in FIG. 14 is meaningless due to the interleaver effect in accordance with LDPC configuration.

A configuration of 2×2 antenna system mentioned in the description of an embodiment of the present invention is the same as shown in FIG. 13. In this case, since a transmitting stage uses precoding, a receiving stage can distinguish a signal from Tx-A and a signal from Tx-B in case of using a transmitting method for throughput improvement.

An embodiment of the present invention can be divided into a first embodiment indicating a case that a signal strength of a receiving signal is changed by a radio channel and a second embodiment in accordance with a situation of applying a different artificial transmission power to a transmitting antenna.

### First Embodiment

A first embodiment of the present invention indicates a case that a signal power of a receiving signal is changed by a radio channel. The received signal power can be directly calculated from RSRP, RSSI, a receiving filter, or the like.

The first embodiment is based on a method of receiving a received signal power using a pilot and/or data resource of an individual antenna. In this case, the first embodiment is non-limited by a power of a received signal but is applicable to any case capable of obtaining a relative size of imbalance occurring in signal powers of streams having passed through the respective channels. For instance, the first embodiment is applicable based on a signal power ratio between received signals, a channel measurement value in MIMO system, or the like.

A transmitting stage can use an existing system in the same manner without adding a special function.

In FIG. 14, a most left node indicates a node for a received signal, a middle node indicates a variable node, and a right node indicates a check node. Although the most left node may be included in the variable node in the bipartite graph of LDPC coding, a received signal node and a variable node are separated from each other in the present invention.

According to the first embodiment, a scaling factor α is applied to the variable node and β is applied to the received signal node, in accordance with a power of a received signal in FIG. 14. The factors α and β can be determined in accordance with a system configuration and a channel environment.

The factor α is changeable as signal transmission and reception are repeated. And, a different factor α may be applicable to each variable node. In a general LDPC decoder, a factor β is set to 1 and a factor β of a punctured variable node may be set to 0.

In LDPC decoding according to the present invention, a value of a soft information generated from handing over a value calculated in a variable node to a check node is multiplied by a scaling factor α(<1). Since α is smaller than 1, it is able to reduce influence affected by a soft information value of a variable node of a poor channel. Hence, a soft information value of a good channel has more influence on iteration decoding. In particular, since a check node value is updated by referring to soft information of a good channel more and each variable node is updated using it, the soft information of the good channel affects a variable node of a poor channel, whereby error performance can be enhanced.

On the other hand, in case of α>1, since soft information of a poor channel has more influence, error performance is degraded. In case of α=1, it indicates a general LDPC decoder. Hence, although a is differentiated for each variable node, it ‘α<1’ should be maintained all the time in order to enhance error performance.

In particular, since it is able to reduce the speed in propagating soft information of a variable node on a poor channel side to all variable nodes and all check nodes using ‘α<1’, error performance can be enhanced.

Meanwhile, if FIG. 12(a) is changed into FIG. 12(b), since a length handed by channel coding is increased, error performance can be enhanced. This is the same phenomenon occurring not in an existing system but in a system of the present invention using FIG. 12(b).

If a received signal of a poor channel side gets worse too much, it may be good for the corresponding nodes not to be used rather than to be used. Hence, if a reference value (e.g., a received power of a poor channel side, a power ratio, etc.) for determining a and β gets equals to or smaller than a predetermined value, it is preferable that a signal received from a channel is not used by setting β=0 in FIG. 14. If β=0, since soft information of a good channel side is used only for iteration decoding, it results in a puncturing form of general LDPC coding. In this case α is set to 1.

The first embodiment of the present invention mentioned in the foregoing description is applicable to a CA system using N carriers to transmit total N streams by having at least two transmitting/receiving antennas, a multi-antenna system using at least N transmitting/receiving antennas, and the like.

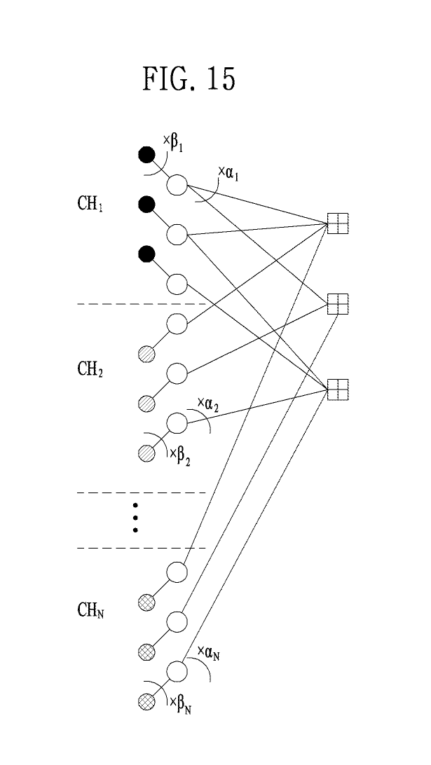

FIG. 15 shows a bipartite graph of an LPDC decoder, to which a scaling factor is applied, in a system for N stream transmissions. To symbols received through a plurality of channels CH1 to CHN for the respective streams, α and β values can be applied per channel. If all the α and β values are ‘1’, it indicates a general LDPC decoder.

### Second Embodiment

A second embodiment of the present invention relates to a case that a different artificial transmission power is applied to transmitting antenna.

The second embodiment relates to a case of applying a different transmission power per transmitting antenna, whereas the first embodiment relates to a case of applying the same transmission power to each transmitting antenna. Preferably, the second embodiment is applied to an active antenna system having PA (power amplifier) provided to an individual antenna, as shown in FIG. 10.

For instance, if an antenna of an upper block has a transmission power greater than that of an antenna of a lower block in FIG. 11, it can be regarded as the same as the occurrence of the received power imbalance ΔG in FIG. 11.

Hence, like the first embodiment of the present invention, it is able to set the values α and β by finding a power of a received signal. Subsequently, the features of the second embodiment are applicable in the same manner of the first embodiment.

According to embodiments of the present invention, it is able to improve error performance in a situation that a retransmission scheme is not usable due to a rapid change of a channel environment. And, it is able to improve error performance using α and β values according to a channel situation without changing modulation and coding level through AMC. In case of LTE system, although 4 bits are assigned for modulation and coding level change through AMC, it is able to reduce the assigned bits by applying the present invention instead. Since modulation and coding level change period can be reduced through AMC, it is able to increase a CQI reporting interval. When a per-antenna transmission power difference is generated, it is able to improve an information error of a small power side.

Base Station and User Equipment Available for Embodiment of Present Invention

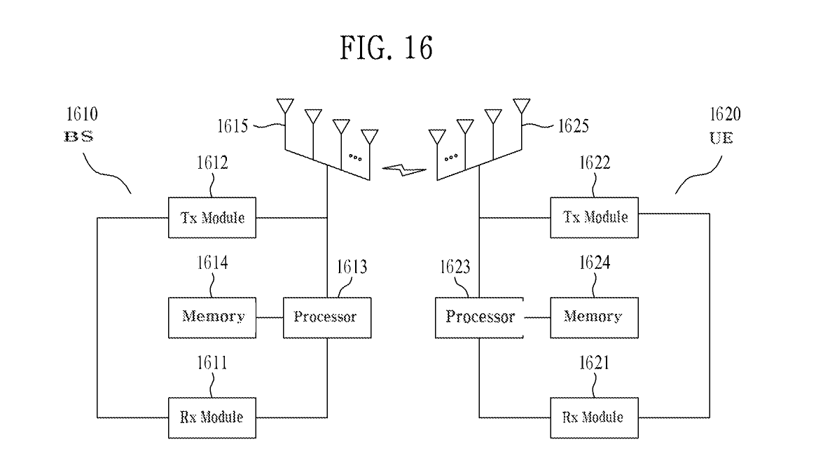

FIG. 16 shows one example of a base station and user equipment applicable to one embodiment of the present invention.

In case that a relay is included in a wireless communication system, a communication in backhaul link is performed between a base station and a relay and a communication in access link is performed between the relay and a user equipment. Hence, the base station or user equipment shown in the drawing can be substituted with the relay under circumstances.

Referring to FIG. 16, a wireless communication system includes a base station (BS) 1610 and a user equipment (UE) 1620. The base station 1610 includes a processor 1612, a memory 1614, and a Radio Frequency (RF) unit 1616. The processor 1612 may be configured to perform the proposed procedures and/or methods according to the present invention. The memory 1614 is connected to the processor 1612 and stores various kinds of information related to operations of the processor 1612. The RF unit 1616 is connected to the processor 1612 and transmits and/or receives radio signals. The user equipment 1620 includes a processor 1622, a memory 1624, and an RF unit 1626. The processor 1622 may be configured to perform the proposed procedures and/or methods according to the present invention. The memory 1624 is connected to the processor 1622 and stores various kinds of information related to operations of the processor 1622. The RF unit 1626 is connected to the processor 1622 and transmits and/or receives radio signals. The base station 110 and/or the user equipment 120 may include a single antenna or multiple antennas.

The embodiments of the present invention described above are combinations of elements and features of the present invention in a predetermined form. The elements or features may be considered selective unless otherwise mentioned. Each element or feature may be practiced without being combined with other elements or features. Further, an embodiment of the present invention may be constructed by combining parts of the elements and/or features. Operation orders described in embodiments of the present invention may be rearranged. Some constructions of any one embodiment may be included in another embodiment and may be replaced with corresponding constructions of another embodiment. It is obvious to those skilled in the art that claims that are not explicitly cited in each other in the appended claims may be presented in combination as an embodiment of the present invention or included as a new claim by a subsequent amendment after the application is filed.

In this disclosure, a specific operation explained as performed by a base station may be performed by an upper node of the base station in some cases. In particular, in a network constructed with a plurality of network nodes including a base station, it is apparent that various operations performed for communication with a terminal can be performed by a base station or other networks except the base station. A base station may be substituted with such a terminology as a fixed station, a Node B, an eNode B (eNB), an access point (AP), or the like.

The embodiments of the present invention may be achieved by various means, for example, hardware, firmware, software, or a combination thereof. In a hardware configuration, the methods according to exemplary embodiments of the present invention may be achieved by one or more application specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, etc.

In a firmware or software configuration, an embodiment of the present invention may be implemented in the form of a module, a procedure, a function, etc. Software code may be stored in a memory unit and executed by a processor.

The memory unit is located at the interior or exterior of the processor and may transmit and receive data to and from the processor via various known means.

Those skilled in the art will appreciate that the present invention may be carried out in other specific ways than those set forth herein without departing from the spirit and essential characteristics of the present invention. The above embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein.

### INDUSTRIAL APPLICABILITY

The embodiments of the present invention mentioned in the foregoing description may be applicable to wireless communication devices such as user equipments, relays, base stations and the like.

What is claimed is:

1. A method of receiving a signal by a user equipment in a wireless communication system, the method comprising:
receiving N signals through N channels; and
decoding the N signals using an Low density parity check (LDPC) sum-product channel decoder,
wherein a first weight factor is applied to a variable node of the LDPC sum-product channel decoder,
wherein a second weight factor is applied to a received signal node, and
wherein the first weight factor is smaller than 1 for a channel having a channel state equals to or smaller than a reference value among the N channels.

2. The method of claim 1, wherein the first weight factor is separately set for each of the N channels.

3. The method of claim 1, wherein the second weight factor is set to 0 if the channel state is equals to or smaller than a minimum value.

4. The method of claim 1, wherein the N signals are separately transmitted on the N channels after being processed sequentially according to a single channel coding module, a modulation module and a resource mapping module.

5. The method of claim 1, wherein each of the first weight factor and the second weight factor is determined in accordance with a strength of the signal.

6. The method of claim 5, wherein the strength of the signal is determined based on Reference signal received power (RSRP).

7. The method of claim 5, wherein the strength of the signal is determined based on Received signal strength indicator (RSSI).

8. A user equipment receiving a signal in a wireless communication system, the user equipment comprising:
a radio frequency (RF) unit; and
a processor,
wherein the processor is configured to:
receive N signals through N channels, and
decode the N signals using an Low density parity check (LDPC) sum-product channel decoder,
wherein a first weight factor is applied to a variable node of the LDPC sum-product channel decoder,
wherein a second weight factor is applied to a received signal node, and
wherein the first weight factor is smaller than 1 for a channel having a channel state equals to or smaller than a reference value among the N channels.

9. The user equipment of claim 8, wherein the first weight factor is separately set for each of the N channels.

10. The user equipment of claim 8, wherein the second weight factor is set to 0 if the channel state is equals to or smaller than a minimum value.

11. The user equipment of claim 8, wherein the N signals are separately transmitted on the N channels after being processed sequentially according to a single channel coding module, a modulation module and a resource mapping module.

12. The user equipment of claim 8, wherein each of the first weight factor and the second weight factor is determined in accordance with a strength of the signal.

13. The user equipment of claim 12, wherein the strength of the signal is determined based on Reference signal received power (RSRP).

14. The user equipment of claim 12, wherein the strength of the signal is determined based on Received signal strength indicator (RSSI).
